(19) United States
(12) Patent Application Publication
(10) Pub. No.: US 2006/0218467 A1
(43) Pub. Date: Sep. 28, 2006

(54) Memory having a portion that can be switched between use as data and use as error correction code (ECC)

(76) Inventors: James M. Sibigtroth, Round Rock, TX (US); Brian E. Cook, Austin, TX (US); George L. Espinor, Austin, TX (US); Clay E. Merritt, Austin, TX (US); Bruce L. Morton, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/088,562

(22) Filed: Mar. 24, 2005

(51) Int. Cl. G11C 29/00

(52) U.S. Cl. 714/763

(57) ABSTRACT

A memory has an ECC-enabled mode and an ECC-disabled mode in which the portion of the memory dedicated to use as storing ECC in the ECC-enabled mode is used for storing general purpose information (data) in the ECC-disabled mode. This is achieved in a non-volatile memory (NVM) by having the data and the portion of the memory with the corresponding ECC on the same word line. This is particularly important in an NVM because of complication relating to erase. In the ECC-enabled mode the ECC and corresponding data should be erased, programmed, and read together in order to avoid a significant layout and performance penalty. This is best achieved by having the ECC and the data on the same word line.

### FIELD OF THE INVENTION

This invention relates to memories, and more particularly to memories that have a portion that can be switched between use as data and use as ECC.

### BACKGROUND OF THE INVENTION

One of the techniques used in computing systems is error correction. Error correction, however, is not used in all computing systems because some applications are much more error tolerant than others. There have been attempts to make a memory system more flexible by having a mode for error correction and a mode that does not use error correction. In the case of no error correction, the portion of the memory system used for storing the error correction code (ECC) is used as general purpose (data) memory.

One of the difficulties has been applying this type of approach to a single integrated circuit, especially when the memory is a non-volatile memory (NVM).

Thus there is a need for an approach for switching a memory between use in storing ECC and in storing data that overcomes or reduces the adverse effects of these issues.

### BRIEF DESCRIPTION OF THE DRAWINGS

The foregoing and further and more specific objects and advantages of the instant invention will become readily apparent to those skilled in the art from the following detailed description of a preferred embodiment thereof taken in conjunction with the following drawings:

FIG. 1 is a block diagram of a memory according one embodiment of the invention;

FIG. 2 is a block diagram of a portion of the memory of FIG. 1;

FIG. 3 is a block diagram that shows a more detailed portion of the portion in FIG. 2 of the memory of FIG. 1;

FIG. 4 is a memory map of the memory of FIG. 1 in an ECC-enabled mode; and

FIG. 5 is a memory map of the memory of FIG. 1 in an ECC-disabled mode.

### DETAILED DESCRIPTION OF THE PREFERRED EMBODIMENT

In one aspect, a memory has an ECC-enabled mode and an ECC-disabled mode in which the portion of the memory dedicated to use as storing ECC in the ECC-enabled mode is used for storing general purpose information (data) in the ECC-disabled mode. This is achieved in a non-volatile memory (NVM) by having the data and the portion of the memory with the corresponding ECC on the same word line. This is particularly important in an NVM because of complications relating to erase. In the ECC-enabled mode the ECC and corresponding data should be erased, programmed, and read together to avoid a significant layout and performance penalty. This is best achieved by having the ECC and the data on the same word line. This is better understood with reference to the drawings and the following description.

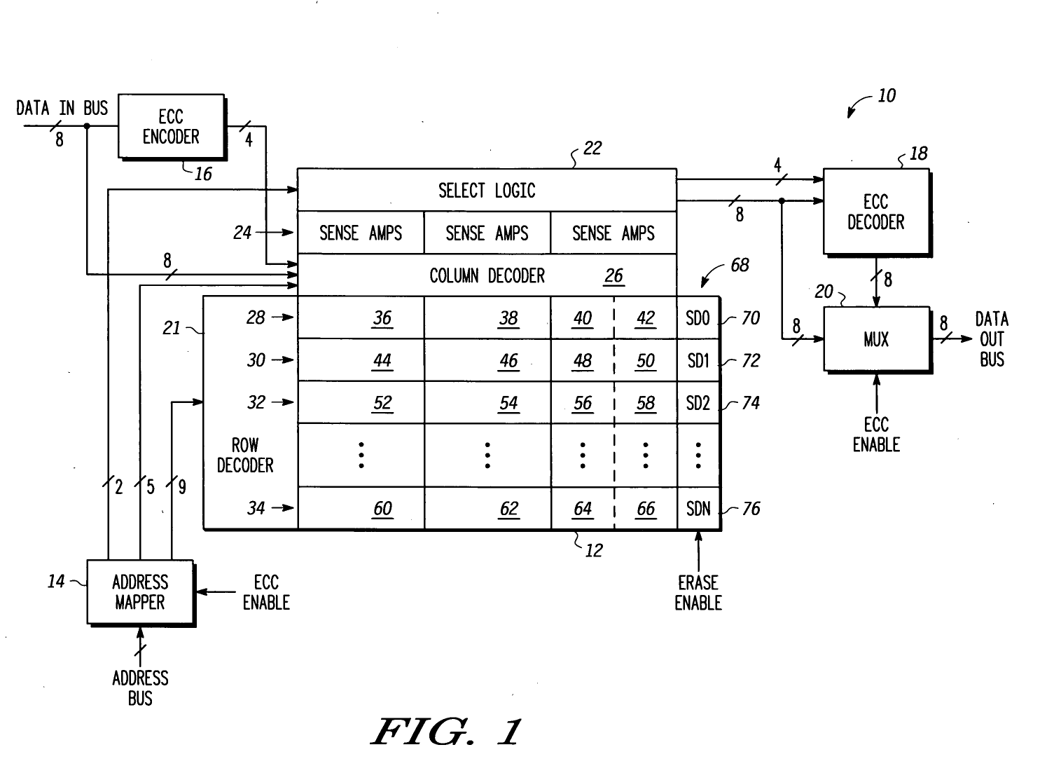

Shown in FIG. 1 is a memory 10 having an array 12 of NVM cells, an address mapper 14, an error correction code (ECC) encoder 16, an ECC decoder 18, a multiplexer (mux) 20, a row decoder 21, select logic 22, a plurality of sense amplifiers 24, and a column decoder 26. Array 12 comprises a sector 28, a sector 30, a sector 32, and a sector 34. Sector 28 comprises sub-sectors 36, 38, 40, and 42. Sector 30 comprises sub-sectors 44, 46, 48, and 50. Sector 32 comprises sub-sectors 52, 54, 56, and 58. Sector 34 comprises sub-sectors 60, 62, 64, and 66. Memory 10 also comprises a plurality of source drivers 68 that comprises source drivers 70, 72, 74, and 76.

Address mapper 14 has a first input for receiving an address from an address bus, and a second input for receiving an ECC-enable signal, a first output coupled to select logic 22, a second output coupled to column decoder 26, and a third output connected to row decoder 21. ECC encoder 16 has an input for receiving data from a data-in bus and an output coupled to column decoder 26. ECC decoder 18 has a first input coupled to select logic 22, a second input coupled to select logic 22, and an output coupled to mux 20. Mux 20 has a first input coupled to select logic 22, a second input coupled to the output of ECC decoder 18, a third input for receiving the ECC enable signal, and an output for providing data to a data-out bus. Row decoder 21 has an input connected to the third output of address mapper 14 and outputs connected to sectors 28-34. Select logic 22, which is coupled to plurality of sense amplifiers 24, has a first input connected to the first output of address mapper 14, a first output coupled to the first input of ECC decoder 18, and a second output connected to the second input of ECC decoder 18 and to the first input of mux 20. Plurality of sense amplifiers 24 is connected between column decoder 26 and select logic 22. Column decoder 26, which is coupled to array 12 and plurality of sense amplifiers 24, has a first input connected to the second output of address mapper 14, a second input connected to the data-in bus, and third input connected to the output of ECC encoder 16.

Although only four sectors are actually shown in FIG. 1, in this example, there are 64 sectors in total for memory 10. Plurality of source drivers (SD) 68 are connected to sectors 28-34. Source driver 70 is connected to sector 28. Source driver 72 is connected to sector 30. Source driver 74 is connected to sector 32, and source driver 76 is connected to sector 34. Each of sectors 28-34 comprise 8 rows of memory cells and are constructed the same.

Sector 28 is shown in FIG. 2 as being connected to row decoder 21 and is exemplary of each of sectors 28-34. Sector 28, as stated previously, comprises sub-sectors 36, 38, 40, and 42. Sector 28 also comprises rows 78, 80, 82, 84, 86, 88, 90, and 92 having word lines 94, 96, 98, 100, 102, 104, 106, and 108, respectively. Each of rows 78-92 comprises a portion from sub-sector 36, a portion from sub-sector 38, a portion of sub-sector 40, and a portion of sub-sector 42. Row 78, for example, comprises a portion 110 from sub-sector 36, a portion 112 from sub-sector 38, a portion 114 from sub-sector 40, and a portion 116 from sub-sector 42. Thus portions 110, 112, 114, and 116 each include a portion of word line 94. In this example, portions 110 and 112 each comprise 256 cells connected to word line 94, wherein each memory cell stores 1 bit of information. Portions 114 and 16 each comprise 128 memory cells connected to word line 94. Similarly row 80 comprises portions 120, 122, 124, and 126 that are part of subsections 36, 38, 40, and 42, respectively, and have 256, 256, 128, and 128 memory cells, respectively, that are connected to word line 96. In the same way row 82 comprises portions 130, 132, 134, and 136 that are part of subsections 36, 38, 40, and 42, respectively, and have 256, 256, 128, and 128 memory cells, respectively, that are connected to word line 98. The remaining rows 84-92 similarly comprise portions connected to word lines 100-108, respectively, in the same manner as for rows 78, 80, and 82.

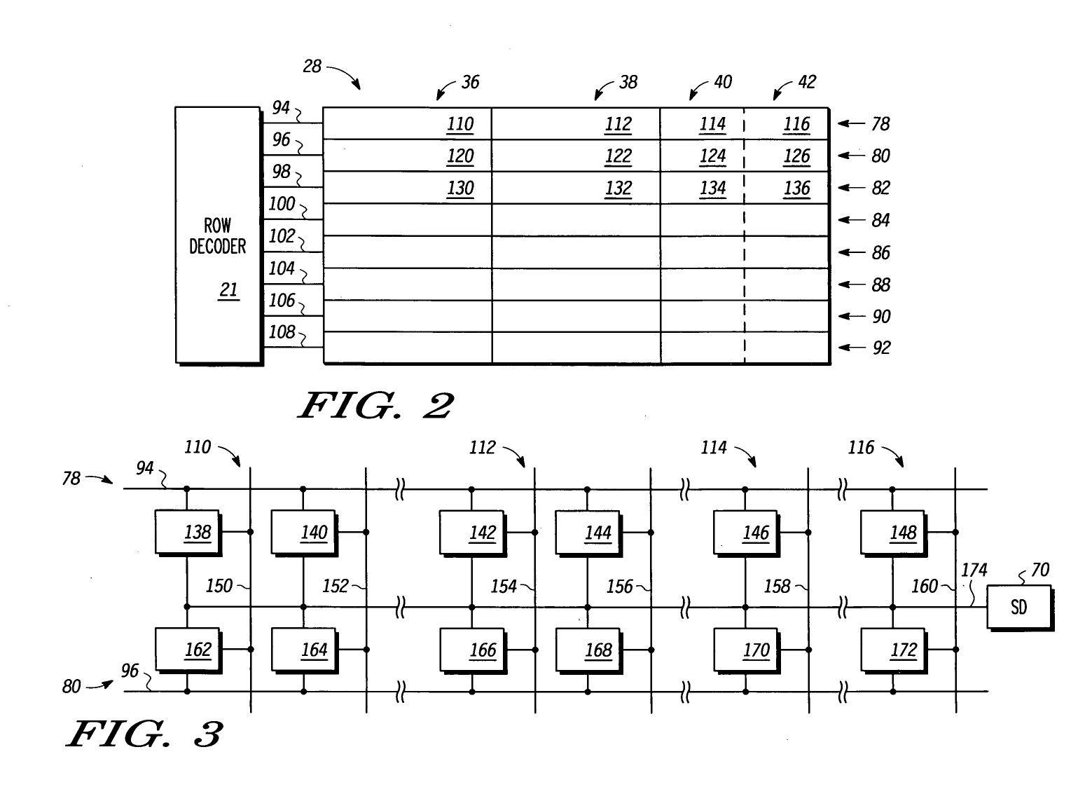

Shown in FIG. 3 are row 78 having word line 94 with memory cells 138, 140, 142, 144, 146, and 148 connected thereto and row 80 having word line 96 with memory cells 162, 164, 166, 168, 170, and 172 connected thereto. Also shown are bit lines 150, 152, 154, 156, 158, and 160 connected to memory cells 138, 140, 142, 144, 146, and 148, respectively, and 162, 164, 166, 168, 170, and 172, respectively. In conventional fashion word lines 94 and 96 run perpendicular to bit lines 150-160. Memory cells connected to the same bit line form a column. Thus, for example, memory cells 138 and 162 are in the same column and are part of portion 110. Memory cells 166 and 142 are in the same column and part of portion 112. Memory cells 146 and 170 are in the same column and are part of portion 114. Similarly, memory cells 148 and 172 are in the same column and are part of portion 116.

Also shown in FIG. 3 is source driver 70 that is connected to a source line 174 that in turn is connected to all of the memory cells in rows 78 and 80. Further, this line 174 is shorted to other source lines connected to the memory cells in rows 82 84, 86, 88, 90, and 92. All of the memory cells of sector 28 are connected in common to source driver 70.

In operation memory 10 has two modes of operation concerning the use of ECC; an ECC-enabled mode and an ECC-disabled mode. For a read in the ECC-enabled mode, a row is selected by row decoder 21 by enabling the word line, and a data byte and the corresponding ECC information in the selected row are coupled by column decoder 26 and select logic 22 to ECC decoder 18. Mux 20 then couples the output received from ECC decoder 18 onto the data-out bus. Address mapper 14 couples the row address portion of the address to row decoder 21 and the column portion of the address to column decoder 26 and select logic 22. Sense amplifiers 24 comprise a total of 24 sense amplifiers. Eight of the sense amplifiers are for sensing the logic state of memory cells from the group of sub-sectors comprising sub-sectors 36, 44, 52, and 60. Eight of the sense amplifiers are for sensing the logic state of memory cells from the group of sub-sectors comprising sub-sectors 38, 46, 54, and 62. Four of the sense amplifiers are for detecting the logic state of memory cells from the group of sub-sectors comprising sub-sectors 40, 48, 56, and 64. Four of the sense amplifiers are for detecting the logic state of memory cells of the group of sub-sectors comprising sub-sectors 42, 50, 58, and 66.

Using a selection from sub-sector 36 as an example, row decoder 21 selects a row from sector 28 by enabling a word line such as word line 94 shown in FIG. 3. Column decoder 26 couples the selected eight bit lines that traverse sub-sectors 36, 44, 52, and 60 to sense amplifiers 24. The corresponding eight sense amplifiers are enabled to detect the logic state of the memory cells that are coupled to the selected word line and bit lines. Also four bit lines that traverse sub-sectors 40, 48, 56, and 64 are coupled to four sense amplifiers of sense amplifiers 24. Similarly the four sense amplifiers that are coupled to the selected bit lines are enabled and detect the logic state of the four memory cells connected to the selected word line and the four selected bit lines. Select logic 22 couples the outputs of the enabled twelve sense amplifiers to ECC decoder 18 while decoupling the disabled sense amplifiers from ECC decoder 18. In the ECC enabled mode, mux 20 couples the output of ECC decoder 18 to the data-out bus.

Thus, it is seen that the memory cells that provide the eight data bits are connected to the same word line as the memory cells that provide the corresponding four ECC information bits. Also there are eight bits of data from each of the data sub-sectors from a selected sector and a total of eight bits of ECC from two sub-sectors from the selected sector. During erase, a sector is selected for being erased by row decoder 21 selecting all word lines in the sector to be erased. Thus, for example, if sector 28 is to be erased, row decoder 21 in response to address mapper 14 enables all of the word lines of sector 28. Since all of the memory cells of a sector are erased at the same time, the data and the corresponding ECC information is similarly erased at the same time. It is useful to avoid having a different word line for the data than for the corresponding ECC information because that would increase both circuit and layout to achieve reading, programming, and erase.

For programming in the ECC-enabled mode, data comes to ECC encoder 16 from the data-in bus. ECC encoder 16 provides the ECC information to column decoder 26 based on the data on the data bus. Row decoder 21 selects a row by enabling the word line of the selected row and that causes the corresponding source driver to be activated to supply a programming voltage. Column decoder 26 sinks the needed programming current on the selected bit lines for the data portion of the memory and for the ECC portion. For example, for the case of writing data into sub-sector 36 of sector 28, a row is selected in sector 28, eight bit lines that run through sub-sector 36 carry the program levels for data on the selected bit lines as driven by column decoder 26, and the four bit lines that run through sub-sector 40 carry the program levels for ECC information as driven by column decoder 26. Thus, the same column decoder and row decoder are used for programming both the selected data location and the ECC information location. This helps avoid excessive layout and circuit complexities.

The eight bits used for ECC information in the ECC-enabled mode are available for data in the ECC-disabled mode. For example, the memory cells in sub-sectors 40, 42, 48, 50, 56, 58, 64, and 66 are available for use as data. There are eight sense amplifiers committed to those sub-sectors so that a full byte of data from a given word line access is available from the portion of the memory that was used for ECC information in the ECC-enabled mode. This is achieved by configuring the address mapper to recognize a different address for a given word line. Thus, for example, a particular address on the address bus, may result in a different row in memory 10 being selected. A given address that would select word line 96 during the ECC-enabled mode, would result in a different word line being selected during the ECC-disabled mode. In effect, there is a decode for three bytes on a given word line instead of two bytes. Another difference is that all eight of the sense amplifiers that are coupled to the bit lines that run through the ECC portion of the memory are enabled when that portion of the memory is selected during the ECC-enabled mode. The erase operation is the same for both the ECC-enabled and ECC-disabled mode.

Using a selection of a byte from sub-sectors 40 and 42 as an example, address mapper 14 provides the address to row decoder 21 that causes a word line passing through sub-sectors 40 and 42 to be enabled. Similarly, column decoder 26 couples the selected bit lines that pass through sub-sectors 40 and 42 to the eight sense amplifiers for ECC information bits. All eight of the sense amplifiers for ECC information bits are enabled and they detect the logic state of memory cells that are connected to the selected word line and eight selected bit lines. Select logic passes the output of these eight sense amplifiers to mux 20. Mux 20 then provides the output of the sense amplifiers to the data-out bus.

For the program operation, the column decoder 26 provides the appropriate program levels to the selected eight bit lines that pass through sub-sectors 40 and 42. Select logic 22 provides the necessary signals to column decoder 26 to select eight bit lines instead of just four that are selected in the ECC-enabled mode. This remapping of the address scheme provides for an effective use of the ECC portion of the memory as a data memory while maintaining the layout and circuit simplicity of having the data and corresponding ECC portions in the same row.

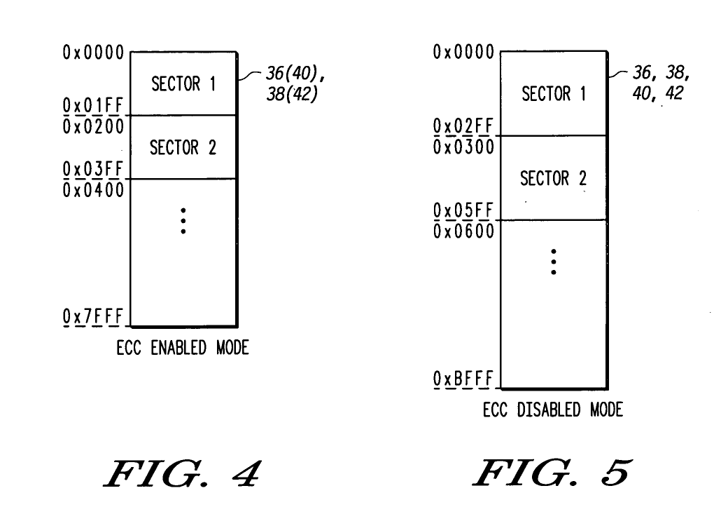

Shown in FIG. 4 is a memory map of memory 10 for the ECC-enabled mode. In this case, the first sector, which comprises sub-sectors 36 and 38 with corresponding ECC sub-sectors 40 and 42, respectively, comprises a memory space from 0x0000 to 0x01FF. The second sector comprises a memory space 0x0200 to 0x03FF. In this example, the total memory space extends to 0x7FFF.

Shown in FIG. 5 is a memory map of memory 10 for the ECC-disabled mode. In this case the first sector, which comprises sub-sectors 36, 38, 40, and 42 for data, comprises a memory space from 0x0000 to 0x02FF. This shows not only the increase in memory space for data in the ECC-disabled mode, but also the remapping of the memory space with regard to the sectors. For example, the memory space from 0x0200 to 0x02FF is in the rows of the first sector, which comprises sub-sectors 36, 38, 40, and 42 for the ECC-disabled mode, but for the ECC-enabled case these same addresses are in the second sector and thereby in different rows. The second sector for the ECC-disabled case has a memory space that extends from 0x0300 to 0x05FF. Memory 10 in the ECC-disabled mode extends ultimately to 0xBFFF, which is a 50% increase over the ECC-enabled case.

Various changes and modifications to the embodiments herein chosen for purposes of illustration will readily occur to those skilled in the art. For example, although an NVM was discussed that used a source driver for programming was described and that there are particular benefits for NVM, that does not preclude the possibility that other memories may be used. In this example, specific numbers of memory cells, word lines, and bit lines were described, but these were given as an example and other size memories with other arrangements may also be used. The specifics of the memory mapping are a further example of the specific size being given as an example and that other sizes may be used. To the extent that such modifications and variations do not depart from the spirit of the invention, they are intended to be included within the scope thereof which is assessed only by a fair interpretation of the following claims.

1. A memory comprising:
a first plurality of memory cells in a memory array, wherein each memory cell of the first plurality of memory cells is coupled to a word line, the first plurality of memory cells comprising:
a second plurality of memory cells, the second plurality of memory cells configured to store data; and
a third plurality of memory cells, wherein in a first mode, the third plurality of memory cells is configured to store data, wherein in a second mode, the third plurality of memory cells is configured to store error correction code information.

2. The memory of claim 1 wherein:
in the second mode, memory cells of the third plurality of memory cells are configured to store error correction code information for data stored in memory cells of the second plurality of memory cells.

3. The memory of claim 1 further comprising:
a fourth plurality of memory cells wherein each memory cell of the fourth plurality of memory cells is coupled to a second word line, the fourth plurality of memory cells comprising:
a fifth plurality of memory cells, the fifth plurality of memory cells configured to store data; and
a sixth plurality of memory cells, wherein in the first mode, the sixth plurality of memory cells is configured to store data, wherein in the second mode, the sixth plurality of memory cells is configured to store error correction code information.

4. The memory of claim 3 wherein:
the second plurality of memory cells are located in a first set of columns of the memory array;
the fifth plurality of memory cells are located in the first set of columns of the memory array;
the third plurality of memory cells are located in a second set of columns of the memory array; and
the sixth plurality of memory cells are located in the second set of columns of the memory array.

5. The memory of claim 1 wherein the memory cells of the first plurality are characterized as non volatile memory cells.

6. The memory of claim 1 wherein the memory cells of the first plurality are characterized as flash memory cells.

7. The memory of claim 1 wherein the second plurality of memory cells and the third plurality of memory cells are erased in a first erase operation.

8. The memory of claim 7 further comprising:
a fourth plurality of memory cells, coupled to a second word line, wherein the memory cells of the fourth plurality are not erased during the first erase operation.

9. The memory of claim 1 further comprising:
a data bus; and
an error correction code circuit;
wherein in the first mode, the data bus receives data from a group of memory cells of the third plurality of memory cells in response to a read request addressed to the group of memory cells of the third plurality; and
wherein in the second mode, the error correction code circuit receives data from a group of memory cells of the second plurality of memory cells and error correction code information from a group of memory cells of the third plurality of memory cells in response to a read request addressed to the group of memory cells of the second plurality.

10. The memory of claim 1 wherein:
in the first mode, the data bus receives data from a group of memory cells of the third plurality of memory cells in response to a read request addressed to the group of memory cells; and
in the second mode, the data bus can not receive information stored in the third plurality of memory cells.

11. The memory of claim 1 further comprising:
an address bus, the address bus receiving addresses for accesses to memory cells of the memory array;
row decoder circuitry and column decoder circuitry for the memory array; and
an address mapper circuit coupled to the address bus, the address mapper circuit including outputs coupled to the row decoder circuitry and the column decoder circuitry;
wherein the memory cells of the second plurality are located in a first set of columns of the memory array;
wherein in the first mode, the address mapper decodes a first read address from the address bus to drive its outputs coupled to the row decoder circuitry and the column decoder circuitry as per a first decode pattern to read data stored in memory cells of the third plurality; and
wherein in the second mode, the address mapper decodes the first read address from the address bus to drive its outputs coupled to the row decoder circuitry and the column decoder circuitry as per a second decode pattern to read data stored in memory cells located in columns of the first set of columns.

12. A method of operating a memory, the memory including a first plurality of memory cells coupled to a word line, the first plurality of memory cells including a second plurality of memory cells and a third plurality of memory cells, the method comprising:
wherein in a first mode:
storing data in the second plurality of memory cells; and
storing data in the third plurality of memory cells; and
wherein in a second mode:
storing data in the second plurality of memory cells and storing error correction code information in the third plurality of memory cells.

13. The method of claim 12 wherein:
in the second mode, memory cells of the third plurality of memory cells store error correction code information for data stored in memory cells of the second plurality of memory cells.

14. The method of claim 12 wherein the memory cells of the first plurality are characterized as non volatile memory cells.

15. The method of claim 12 wherein the memory cells of the first plurality are characterized as flash memory cells.

16. The method of claim 12 wherein the second plurality of memory cells and the third plurality of memory cells are erased in a first erase operation.

17. The method of claim 16 wherein:
the memory further comprises a fourth plurality of memory cells, coupled to a second word line;
wherein the memory cells of the fourth plurality are not erased during the first erase operation.

18. The method of claim 12 further comprising:
wherein in the first mode, providing data from a group of memory cells of the third plurality of memory cells to a data bus in response to a read request addressed to the group of memory cells of the third plurality; and
wherein in the second mode, providing data from a group of memory cells of the second plurality of memory cells to an error correction code circuit and providing error correction code information from a group of memory cells of the third plurality of memory cells in response to a read request addressed to the group of memory cells of the second plurality of memory cells.

19. The method of claim 12 further comprising:
wherein in the first mode, providing data to a data bus from a group of memory cells of the third plurality of memory cells in response to a read request addressed to the group of memory cells; and
wherein in the second mode, the data bus can not receive information stored in the third plurality of memory cells.

20. The method of claim 12 wherein the memory cells of the third plurality are located in a first set of columns of a memory array, the method further comprising:
receiving a first address from an address bus;
wherein in the first mode, accessing data stored in a group of memory cells located in the first set of columns and providing the data to a data bus in response to the first address; and
wherein in the second mode, accessing data stored in a group of memory cells of the second plurality and accessing error correction code information stored in a group of memory cells of the third plurality and providing the data and the error correction code information to an error correction code circuit in response to the first address.

21. A memory comprising:
a memory array, the memory array including a first plurality of memory cells located in a first set of columns and a second plurality of memory cells located in a second set of columns, wherein the memory array includes a plurality of word lines with memory cells of the first plurality of memory cells and memory cells of the second plurality of memory cells coupled to each word line of the plurality of word lines; and
means for, in a first mode providing data stored in memory cells of the second plurality of memory cells to a data bus, and in a second mode providing data stored in memory cells of the first plurality of memory cells coupled to a word line and error correction code information stored in memory cells of the second plurality coupled to the word line to an error correction code circuit.
